(19) United States
(12) Patent Application Publication
(10) Pub. No.: US 2011/0241068 A1
(43) Pub. Date: Oct. 6, 2011

(54) SEMICONDUCTOR DEVICE AND METHOD FOR MANUFACTURING THE SEMICONDUCTOR DEVICE

(75) Inventors: Yuuji WATANABE, Saitama (JP); Masanori FUKUI, Saitama (JP); Michiaki MARUOKA, Saitama (JP)

(73) Assignee: SHINDENGEN ELECTRIC MANUFACTURING CO., LTD., Tokyo (JP)

(21) Appl. No.: 13/074,333

(22) Filed: Mar. 29, 2011

(30) Foreign Application Priority Data
Mar. 30, 2010 (JP) 2010-077846
Feb. 22, 2011 (JP) 2011-035849

(51) Int. Cl. H01L 29/739; H01L 21/332

(52) U.S. Cl. 257/139; 438/135; 257/E29.197; 257/E21.388

(57) ABSTRACT

A semiconductor device which can make the generation of gate parasitic oscillations more difficult than a semiconductor device of the related art is provided. The semiconductor device includes: a drift layer which is constituted of a reference concentration layer and a low concentration layer; a gate electrode structure; a pair of source regions, a pair of base regions, and depletion-layer extension regions which are formed in the reference concentration layer below the base regions, wherein the depletion-layer extension regions are formed such that a lower surface of the depletion-layer extension region is deeper than a boundary between the low concentration layer and the reference concentration layer and projects into the low concentration layers, and a dVDS/dt-decreasing diffusion layer which contains an n-type impurity at a concentration higher than the concentration of the impurity which the reference concentration layer contains and decreases dVDS/dt when the semiconductor device is turned off is formed on a surface of the reference concentration layer.

### BACKGROUND OF THE INVENTION

1. Field of the Invention

The present invention relates to a semiconductor device and a method for manufacturing the semiconductor device.

2. Description of the Related Art

To explain the related art, there has been known a semiconductor device which can be miniaturized without causing the increase of the ON-resistance of the semiconductor device and has a preferable breakdown voltage characteristic (for example, see International Publication WO2008/069309 pamphlet (patent document 1)). FIG. 8 is a cross-sectional view of such a semiconductor device 90 of the related art.

The semiconductor device 90 of the related art is a power MOSFET and has the following structure. As shown in FIG. 8, the semiconductor device 90 includes: a drift layer 5 which is constituted of a reference concentration layer 4 containing an n-type impurity (an impurity of a first conductive type) at a first reference concentration and a low concentration layer 3 formed below the reference concentration layer 4 and containing an n-type impurity at a concentration lower than the first reference concentration; a gate electrode (a polysilicon layer 11 of the gate electrode structure 20) which is formed above the reference concentration layer 4 by interposing a gate insulation film 9; a pair of source regions (semiconductor regions of a first conductive type) 8a, 8b which is formed on a surface of the reference concentration layer 4 in the vicinity of respective ends of the gate electrode structure 20 and contains an n-type impurity at a concentration higher than the first reference concentration; a pair of base regions 7a, 7b which surrounds the respective source regions 8a, 8b and contain a p-type impurity (an impurity of a second conductive type) at a second reference concentration; a source electrode (first electrode) 14 which is electrically connected to the source regions 8a, 8b and the base regions 7a, 7b; depletion-layer extension regions 6a, 6b which are respectively formed in the reference concentration layer 4 below the base regions 7a, 7b and contain a p-type impurity at a concentration lower than the second reference concentration; a drain layer 2 which is formed below the low concentration layer 3 and contains an n-type impurity at a concentration higher than the first reference concentration; and a drain electrode 1 which is formed below the drain layer 2, a voltage being applied between the source electrode 14 and the drain electrode 1. The depletion-layer extension regions 6a, 6b are formed such that lower surfaces of the depletion-layer extension regions 6a, 6b are deeper than a boundary between the low concentration layer 3 and the reference concentration layer 4, and project into the low concentration layer 3.

According to the semiconductor device 90 of the related art, side surfaces of the base regions 7a, 7b are not covered with the depletion-layer extension regions 6a, 6b and hence, a distance between the opposing base regions 7a, 7b can be narrowed compared to a semiconductor device of the related art (for example, see Japanese Patent 3484690 (patent document 2)) whereby the semiconductor device of the related art can be miniaturized compared to the semiconductor device of the related art. Further, according to the semiconductor device 90 of the related art, the side surfaces of the base regions 7a, 7b are not covered with the depletion-layer extension regions 6a, 6b and hence, even when the distance between the opposing base regions 7a, 7b is narrowed compared to the semiconductor device of the related art, the increase of the ON-resistance of the semiconductor device can be prevented.

Further, according to the semiconductor device 90 of the related art, it is unnecessary to cover the side surfaces of the base regions 7a, 7b with the depletion-layer extension regions 6a, 6b and hence, it is unnecessary to implant a p-type impurity into the base regions 7a, 7b in a wide range whereby the p-type impurity can be deeply implanted into the base regions 7a, 7b with directionality in view of the first reference concentration. Accordingly, it is possible to extend the depletion-layer extension regions 6a, 6b having a sufficient thickness as diffusion layers immediately below bottom portions of diffusion layers of the base regions 7a, 7b so that depletion layers which spread from a PN junction when a reverse bias is applied can be sufficiently extended into the depletion-extension regions 6a, 6b. As a result, an electric field can be sufficiently attenuated due to the extending depletion layers and hence, the lowering of a breakdown voltage caused by the concentration of an electric field can be prevented so that the semiconductor device 90 of the related art can acquire a preferable breakdown voltage characteristic.

Due to such a constitution, the semiconductor device 90 of the related art can be miniaturized without causing the increase of the ON-resistance of the semiconductor device and also can have a preferable breakdown voltage characteristic.

### SUMMARY OF INVENTION

However, it is found that the semiconductor device of the related art 90 has a following drawback. That is, the semiconductor device can be miniaturized without causing the increase of ON-resistance of the semiconductor device and hence, a switching speed is increased. Due to the increase of the switching speed, however, depending on a usage mode of the semiconductor device, gate parasitic oscillations are likely to occur when the semiconductor device is turned off and, in such a case, it is necessary to modify circuit constants to suppress the generation of the gate parasitic oscillations.

The present invention has been made under such circumference, and it is an object of the present invention to provide a semiconductor device in which the occurrence of gate parasitic oscillations is made more difficult compared to the semiconductor device of the related art and a method for manufacturing the semiconductor device.

(1) According to one aspect of the present invention, there is provided a semiconductor device which includes: adrift layer which is constituted of a reference concentration layer containing an impurity of a first conductive type at a first reference concentration and a low concentration layer formed below the reference concentration layer and containing the impurity of a first conductive type at a concentration lower than the first reference concentration; a gate electrode which is formed above the reference concentration layer interposing a gate insulation film; a pair of semiconductor regions of a first conductive type which is formed on a surface of the reference concentration layer in the vicinity of respective end portions of the gate electrode and contains the impurity of a first conductive type at a concentration higher than the first reference concentration; a pair of base regions which surrounds the respective semiconductor regions of a first conductive type and contain an impurity of a second conductive type at a second reference concentration; a first electrode which is electrically connected to the semiconductor regions of a first conductive type and the base regions; and depletion-layer extension regions which are formed in the reference concentration layer below the base regions and contain an impurity of a second conductive type at a concentration lower than the second reference concentration, wherein the depletion-layer extension regions are formed such that a lower surface of the depletion-layer extension region is deeper than a boundary between the low concentration layer and the reference concentration layer and projects into the low concentration layers, and a dVDS/dt-decreasing diffusion layer which contains the impurity of a first conductive type at a concentration higher than the concentration of the impurity which the reference concentration layer contains and decreases dVDS/dt when the semiconductor device is turned off is formed on a surface of the reference concentration layer.

According to the semiconductor device of the present invention, the dVDS/dt-decreasing diffusion layer which contains the impurity of a first conductive type at the concentration higher than the concentration of the impurity which the reference concentration layer contains is formed on the surface of the reference concentration layer and hence, when the switch is turned off, due to an effect of the dVDS/dt-decreasing diffusion layer, it is possible to make the extension of the depletion layer to the dVDS/dt-decreasing diffusion layer from the gate oxide film and the base regions difficult whereby a feedback capacitance Crss between the gate electrode and a drain electrode of the semiconductor device is not rapidly lowered unlike the semiconductor device of the related art. As a result, unlike the semiconductor device of the related art, a voltage VDS between the drain electrode and a source electrode is not rapidly increased and hence, gate parasitic oscillations when the switch is turned off are hardly generated.

Further, the semiconductor device of the present invention has the substantially same structure as the semiconductor device of the related art and hence, the semiconductor device can be miniaturized without causing the increase of the ON-resistance of the semiconductor device, and it is also possible to provide the semiconductor device having a preferable breakdown voltage characteristic.

Further, according to the semiconductor device of the present invention, the resistance immediately below the gate electrode can be lowered and hence, it is possible to reduce the ON-resistance of the semiconductor device compared to the semiconductor device of the related art.

As a result, the semiconductor device of the present invention becomes a semiconductor device which can be miniaturized without causing the increase of the ON-resistance of the semiconductor device, has a favorable breakdown voltage characteristic and can make the generation of gate parasitic oscillations more difficult compared to the semiconductor device of the related art.

(2) In the semiconductor device of the present invention, the dVDS/dt-decreasing diffusion layer may preferably be formed in a region of a surface of the reference concentration layer shallower than the lower surfaces of the base regions.

Due to such a constitution, it is impossible for a thickness of the reference concentration layer to become noticeably thin due to the formation of the dVDS/dt-decreasing diffusion layer and hence, the semiconductor device can maintain the preferable breakdown voltage characteristic as a whole.

(3) In the semiconductor device of the present invention, the dVDS/dt-decreasing diffusion layer may preferably be formed in a region of the surface of the reference concentration layer shallower than a depth which is ½ of a depth of the lower surfaces of the base regions.

Due to such a constitution, the reference concentration layer can be made thicker than the reference concentration layer and hence, the semiconductor device can maintain a preferable breakdown voltage characteristic as a whole.

(4) In the semiconductor device of the present invention, the dVDS/dt-decreasing diffusion layer may preferably contain the impurity of a first conductive type at a concentration lower than a concentration of the impurity of a second conductive type which the base region contains.

Due to such a constitution, in manufacturing the semiconductor device, it is unnecessary to take the interference between the dVDS/dt-decreasing diffusion layer and the base regions into consideration so that the manufacturing process can be simplified.

(5) In the semiconductor device of the present invention, the semiconductor region of a first conductive type may be a source region, the first electrode may be a source electrode, and the semiconductor device may further include a drain layer which is formed below the low concentration layer and contains the impurity of a first conductive type at a concentration higher than the first reference concentration and a drain electrode which is formed below the drain layer, a voltage being applied between the first electrode and the drain electrode, and the semiconductor device may be a MOSFET.

(6) In the semiconductor device of the present invention, the semiconductor region of a first conductive type may be an emitter region, the first electrode may be an emitter electrode, and the semiconductor device may include a collector layer which is formed below the low concentration layer and contains an impurity of a second conductive type, and a collector electrode which is formed below the collector layer, a voltage being applied between the first electrode and the collector electrode, and the semiconductor device may be an IGBT.

(7) In the semiconductor device of the present invention, the semiconductor region of a first conductive type may be an emitter region, the first electrode may be an emitter electrode, and the semiconductor device may include a barrier metal layer which is formed below the low concentration layer, a voltage being applied between the first electrode and the barrier metal layer, and the semiconductor device may be an IGBT which may include a Schottky junction.

(8) According to another aspect of the present invention, there is provided a method for manufacturing a semiconductor device using a semiconductor substrate which includes a low concentration layer containing an impurity of a first conductive type, the method including the steps of: forming a drift layer which is constituted of a reference concentration layer and a low concentration layer, the reference concentration layer being formed by implanting an impurity of a first conductive type at a first reference concentration higher than the impurity concentration of the low concentration layer into the low concentration layer and by thermal diffusion; forming depletion-layer extension regions by implanting an impurity of a second conductive type into regions of the reference concentration layer which are spaced-apart from each other by a predetermined distance; performing thermal diffusion for activating the impurity of a second conductive type implanted into the depletion-layer extension regions; forming a dVDS/dt-decreasing diffusion layer by implanting the impurity of a first conductive type into the reference concentration layer and by performing thermal diffusion; forming a gate pattern between the depletion-layer extension regions by forming an oxide film on the semiconductor substrate and, thereafter, forming a polysilicon layer on the oxide film; forming base regions by implanting an impurity of a second conductive type at a second reference concentration higher than the impurity concentration of the depletion-layer extension regions using the gate pattern as a mask for forming the base regions and by performing thermal diffusion; and forming semiconductor regions of a first conductive type by implanting an impurity of a first conductive type into the base regions at a concentration higher than the first reference concentration using the gate pattern as a mask for forming the semiconductor regions of a first conductive type and by performing thermal diffusion, wherein lower surfaces of the depletion-layer extension regions are positioned deeper than a boundary between the low concentration layer and the reference concentration layer and are formed with a depth where the lower surfaces projects into the low concentration layer.

The above-mentioned semiconductor device of the present invention in (1) can be manufactured by the method for manufacturing a semiconductor device of the present invention.

(9) In the method for manufacturing a semiconductor device of the present invention, the semiconductor device may preferably be a MOSFET, and the semiconductor substrate which includes the low concentration layer containing the impurity of a first conductive type may preferably be a semiconductor substrate which is constituted of a drain layer containing an impurity of a first conductive type at a predetermined concentration, and a low concentration layer which is formed above the drain layer and contains an impurity of a first conductive type at a concentration lower than the predetermined concentration.

Due to such a method, the semiconductor device of the present invention in (5) can be manufactured.

[10] In the method for manufacturing the semiconductor device of the present invention, the semiconductor device may preferably be an IGBT, and the semiconductor substrate which includes the low concentration layer containing the impurity of a first conductive type may preferably be a semiconductor substrate which is constituted of a collector layer containing an impurity of a second conductive type and a low concentration layer which is formed above the collector layer and contains an impurity of a first conductive type.

Due to such a method, the semiconductor device of the present invention (the semiconductor device of the present invention in (6)) can be manufactured.

[11] In the method for manufacturing the semiconductor device of the present invention, the semiconductor device may preferably be an IGBT, the semiconductor substrate which includes the low concentration layer containing the impurity of a first conductive type may preferably be a semiconductor substrate which is constituted of the low concentration layer, and the method may further include a step of forming a barrier metal layer below the low concentration layer.

Due to such a method, the semiconductor device of the present invention in (7) can be manufactured.

### BRIEF DESCRIPTION OF THE DRAWINGS

FIG. 1 is a cross-sectional view of a semiconductor device 10 according to an embodiment;

FIG. 2A is a view showing a step of a method for manufacturing a semiconductor device according to the embodiment;

FIG. 2B is a view showing the step of the method for manufacturing a semiconductor device according to the embodiment;

FIG. 2C is a view showing the step of the method for manufacturing a semiconductor device according to the embodiment;

FIG. 2D is a view showing the step of the method for manufacturing a semiconductor device according to the embodiment;

FIG. 2E a view showing the step of the method for manufacturing a semiconductor device according to the embodiment;

FIG. 2F a view showing the step of the method for manufacturing a semiconductor device according to the embodiment;

FIG. 2G is a view showing the step of the method for manufacturing a semiconductor device according to the embodiment;

FIG. 2H is a view showing the step of the method for manufacturing a semiconductor device according to the embodiment;

FIG. 2I is a view showing the step of the method for manufacturing a semiconductor device according to the embodiment;

FIG. 2J is a view showing the step of the method for manufacturing a semiconductor device according to the embodiment;

FIG. 2K is a view showing the step of the method for manufacturing a semiconductor device according to the embodiment;

FIG. 2L is a view showing the step of the method for manufacturing a semiconductor device according to the embodiment;

FIG. 2M is a view showing the step of the method for manufacturing a semiconductor device according to the embodiment;

FIG. 2N is a view showing the step of the method for manufacturing a semiconductor device according to the embodiment;

FIG. 2O is a view showing the step of the method for manufacturing a semiconductor device according to the embodiment;

FIG. 3 is a graph showing a characteristic of the semiconductor device according to the embodiment;

FIG. 4A to FIG. 4C are graphs for explaining an advantageous effect acquired by the semiconductor device according to the embodiment;

FIG. 5A and FIG. 5B are graphs for explaining an advantageous effect acquired by the semiconductor device according to the embodiment;

FIG. 6 is a cross-sectional view of a semiconductor device according to a modification 1;

FIG. 7 is a cross-sectional view of a semiconductor device according to a modification 2; and

FIG. 8 is a cross-sectional view of a semiconductor device of the related art.

### DETAILED DESCRIPTION OF THE PREFERRED EMBODIMENTS

Hereinafter, a semiconductor device and a method for manufacturing the semiconductor device according to the present invention are explained in conjunction with an embodiment shown in the drawings.

### 1. Constitution of the Semiconductor Device 10

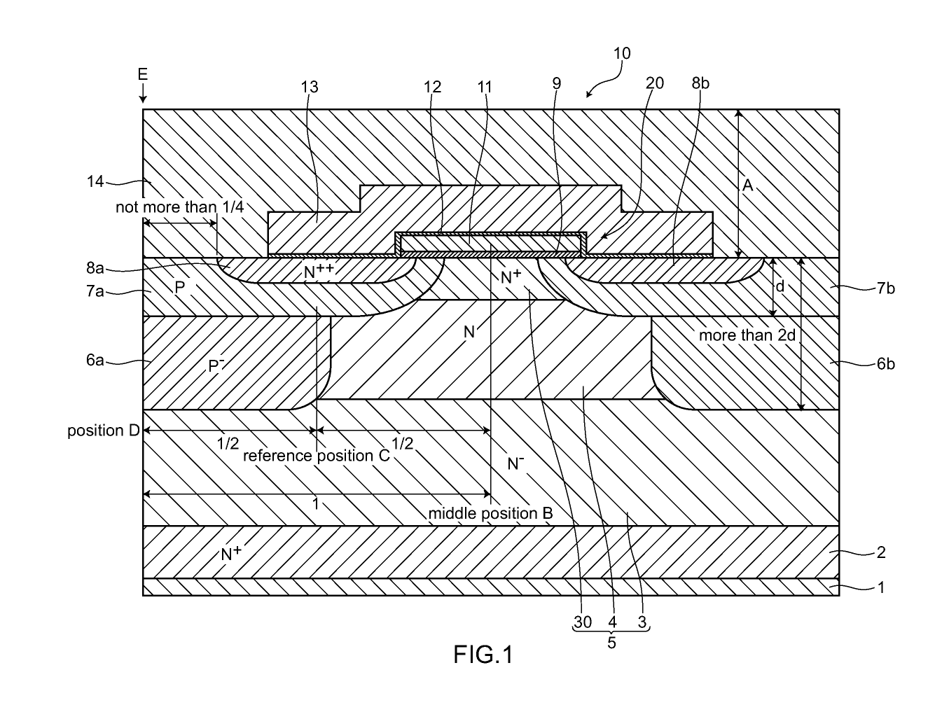

FIG. 1 is a cross-sectional view of the semiconductor device 10 according to the embodiment.

The semiconductor device 10 of this embodiment is a MOSFET (filed-effect transistor) which controls an electric current corresponding to a voltage applied to a gate electrode. Constitutions each of which constitutes the MOSFET are arranged parallel to each other thus provided a plurality of MOSFET constitutions. The respective MOSFETs arranged parallel to each other have the same structure and hence, one of the MOSFET constitutions is explained hereinafter as an example of this embodiment.

As shown in FIG. 1, the semiconductor device 10 of this embodiment includes: a drift layer 5 consisting of a reference concentration layer 4 which containing an n-type impurity as an impurity of a first conductive type at a predetermined first reference concentration and a low concentration layer 3 containing an n-type impurity having a concentration lower than that of the reference concentration layer 4; and the gate electrode structure 20 which is formed on a surface of the reference concentration layer 4. In the vicinity of a surface of the reference concentration layer 4 on which the gate electrode structure 20 is formed, source regions (semiconductor regions of a first conductive type) 8a, 8b which are a pair of diffusion regions respectively formed on a surface of the semiconductor substrate in the vicinity of the opposing end portions of the gate electrode structure 20 at a predetermined distance and contain an n-type impurity having a concentration higher than the first reference concentration are formed. Further, between the respective source regions 8a, 8b and the low concentration layer 3, as diffusion layers which cover the source regions 8a, 8b, base regions 7a, 7b which contains a p-type impurity as an impurity of a second conductive type at a second reference concentration are formed respectively.

Further, in the semiconductor device 10 of this embodiment, bottom surface regions of the diffusion layers of the respective base regions 7a, 7b form depletion-layer extension regions 6a, 6b which contain a p-type impurity at a concentration lower than the second reference concentration. Here, the bottom surface regions indicate, in the case of the diffusion layers of the base regions 7a and 7b, for example, surfaces of planar regions of the bottom portions of the diffusion layers of the base regions 7a and 7b which are parallel to the surface of the semiconductor substrate. The bottom surface of the diffusion layer of the depletion-layer extension region 6 is formed into a shape where the bottom surface projects into the low concentration layer 3 side with respect to the boundary between the reference concentration layer 4 and the low concentration layer 3. That is, the bottom surface of the diffusion layer (boundary between the depletion-layer extension region 6 and the low concentration layer 3) is deeper than the boundary between the low concentration layer 3 and the reference concentration layer 4.

A source electrode (first electrode) 14 is electrically connected to the source regions 8a, 8b, and the base regions 7a, 7b respectively. The drain electrode 1 is an electrode to which a voltage is applied in such a manner that the voltage is applied between the drain electrode 1 and the source electrode 14. The drain electrode 1 is formed on a bottom surface side of the semiconductor substrate of the semiconductor device. Further, a drain layer 2 containing an n-type impurity at a concentration higher than the first reference concentration is formed between the drain electrode 1 and the low concentration layer 3.

In the semiconductor device 10 of this embodiment having the above-mentioned structure, by applying a voltage between the source electrode 14 and the drain electrode 1, and by applying a control voltage to the gate electrode (polysilicon layer 11 of the gate electrode structure 20), a channel (inversion layer) is formed in the base region 7 which is arranged adjacent to the source region 8 and covers the source region 8, and electric current flows between the source electrode 14 and the drain electrode 1 via the drift layer 5 and the drain layer 2.

Further, the reference concentration layer 4 of the drift layer 5 contains phosphorus as an n-type impurity at a surface concentration of 1×10¹⁶ cm⁻³ and has a thickness of approximately 5 to 7 μm, for example. The low concentration layer 3 contains phosphorus as an n-type impurity at a concentration of 3×10¹⁴ cm⁻³ and has a thickness of approximately 40 μm, for example. Further, the drain layer 2 contains phosphorus or antimony as an n-type impurity at a concentration of 1×10²° cm⁻³ and has a thickness of approximately 200 to 300 μm, for example.

At a position A, each source electrode 14 is made of a material containing aluminum as a main component and has a thickness of 4 μm, for example. The drain electrode 1 is formed of a multilayered metal film such as a Ti—Ni—Ag film and has a total thickness of 0.5 μm as the whole multilayered metal film, for example.

As shown in FIG. 1, the gate electrode structure 20 is formed on a surface of the reference concentration layer 4. Further, the gate electrode structure 20 is formed on a surface of the reference concentration layer 4 at a position spaced apart from the pair of source regions 8a, 8b formed in the vicinity of the surface of the reference concentration layer 4.

The gate electrode structure 20 includes a gate oxide film 9 and the polysilicon layer 11 which are formed by stacking sequentially, and further includes an oxide film 12 which covers surfaces of the laminated gate oxide film 9 and polysilicon layer 11. The oxide film 12 covering the surface of the gate oxide film 9 and the surface of the polysilicon layer 11 formed on the gate oxide film 9 extends over a portion of the source region 8a, 8b, and a PSG 13 which constitutes an interlayer insulating film having insulation property is formed on the oxide film 12. Due to the provision of the PSG 13, it is possible to prevent the source electrode 14 and the gate electrode 20 explained later from becoming electrically conductive with each other.

For example, the gate oxide film 9 of the gate electrode structure 20 has a thickness of 0.1 μm, and the polysilicon layer 11 has a thickness of 0.5 μm. For example, the oxide film 12 has a thickness of 0.05 μm and the PSG 13 has a thickness of 1 μm, for example.

In the vicinity of the surface of the reference concentration layer 4 which is arranged directly below the gate electrode structure 20, the opposing source regions 8a, 8b are formed in a spaced-apart manner from each other at a distance of approximately 4 to 6 μm. The source regions 8a, 8b contain arsenic (As) as an n-type impurity at a surface concentration of 2×10²⁰ cm⁻³ and have a depth of approximately 0.3 μm, for example.

The base regions 7a, 7b covering the source regions 8a, 8b face each other in an opposed manner with the reference concentration layer 4 of the drift layer 5 sandwiched therebetween. The base regions 7a, 7b contain for example, boron (B) as a p-type impurity at a surface concentration of 3×10¹⁷ cm⁻³ and have a depth of approximately 2 to 2.5 μm, for example.

The base regions 7a, 7b and the depletion-layer extension regions 6a, 6b which are formed below the bottom surfaces of the base regions 7a, 7b are arranged to face each other in an opposed manner with the drift layer 5 formed immediately below the gate electrode structure 20 sandwiched therebetween. A distance between the base regions 7a, 7b, that is, a lateral width of the drift layer 5 sandwiched between the base regions 7a, 7b is defined as a spaced-apart distance (opposed distance) in the explanation made hereinafter.

Here, one end portion of the depletion-layer extension region 6a facing the depletion-layer extension region 6b in an opposed manner, that is, an end portion of the depletion-layer extension region 6a on a side where the depletion-layer extension region 6a faces the depletion-layer extension region 6b in an opposed manner interposing the drift layer 5 is positioned in the vicinity of a midpoint (reference position C) between a midpoint of the spaced-apart distance (middle position B) and the other end portion E of the depletion-layer extension region 6a which does not face the depletion-layer extension region 6b in an opposed manner interposing the drift layer 5. The end portion E is a repetition point where a plurality of MOSFETs shown in FIG. 1 are contiguously formed. That is, the end portion E is the center of the base region 7a shared in common between the MOSFET shown in FIG. 1 and the MOSFET contiguously formed on a left side of the MOSFET shown in FIG. 1. In the same manner, another adjacent MOSFET contiguously formed on a right side of the MOSFET shown in FIG. 1 also shares the base region 7b in common with the MOSFET shown in FIG. 1. To be more specific, as shown in FIG. 1, assuming a distance between the middle position B at ½ of the lateral width of the gate electrode 20 and the end of the semiconductor device 10 as 1, one end portion of the depletion-layer extension region 6 is arranged at a position in the vicinity of the position C (reference position) at ½ of the distance.

To explain the above in more detail, in FIG. 1 showing the cross section of the semiconductor device, the depletion-layer extension regions 6a, 6b formed in the vicinity of the position C are formed into a curved shape in such a manner that an upper surface of the depletion-layer extension regions 6a, 6b below the bottom surfaces of the base regions 7a, 7b is positioned closer to the inside (in the direction toward the middle position B) of the semiconductor device than the position C, and a lower surface of the depletion-layer extension region 6a is positioned closer to the outside (in the direction toward a position D) of the semiconductor device 10 than the position C. That is, when a voltage is applied between the source electrode 14 and the drain electrode 1 and the MOSFET is in an OFF-state, a depletion layer extending from a boundary between the base region 7a and the reference concentration layer 4 connects with a depletion layer extending from a boundary between the base region 7b and the reference concentration layer 4 at the middle position B therebetween. Further, a depletion layer extending from a boundary between the depletion-layer extension region 6a and the reference concentration layer 4 connects with a depletion layer extending from a boundary between the depletion-layer extension region 6b and the reference concentration layer 4 at the middle position B therebetween.

Preferably, the end portions of the depletion-layer extension regions 6a, 6b having a curved shape are formed into a shape with a curve as sharp as possible rather than a gently-curved shape, and more preferably, except for the upper surface side and the lower surface side of the depletion-layer extension region 6a, 6b, the depletion-layer extension region 6a (6b) should extend as near as possible to the vertical line denoted by the position C shown in FIG. 1 as much as possible, should be positioned slightly closer to the inside (in the direction toward the middle position B) of the semiconductor device than the position C on the upper surface side, and should be slightly closer to the outside (in the direction toward the position C) of the semiconductor device than the position C on the lower surface side in order to have a shape similar to the tip of a so-called Japanese knife used for slicing vegetables and to make the opposing surfaces thereof parallel to each other. The depletion-layer extension regions 6a, 6b are formed in the above manner and hence, the opposed distance between the depletion-layer extension regions 6a and 6b can be widened compared to the corresponding opposed distance in the conventional structure. Accordingly, a region for electrons (carriers) to move can be widened when the semiconductor device is in an ON-state, and the ON-resistance of the semiconductor device can be reduced.

Due to the shape explained above, the spaced-apart distance between the depletion-layer extension regions 6a, 6b which face each other in an opposed manner with the drift layer 5 sandwiched therebetween corresponds to the spaced-apart distance between the curved portions of the diffusion layers forming the depletion-layer extension regions 6a, 6b as shown in FIG. 1 and hence, the spaced-apart distance is gradually increased with the increase of the depth from the upper surface side to the lower surface side.

The depletion-layer extension regions 6a, 6b contain boron as the p-type impurity at a surface concentration of approximately 7×10¹⁶ to 10×10¹⁶ cm⁻³ and have a depth of approximately 7 to 8 μm, for example. Further, with respect to the depletion-layer extension region 6a, 6b, as shown in FIG. 1, a depth to a bottom surface of the depletion-layer extension region 6a, 6b (depth from an upper surface of the reference concentration layer 4 to the bottom surface of the depletion-layer extension region 6) is designed to be more than twice as large as (more than 2d) a depth to the bottom surface of the base region 7 (depth d from the upper surface of the reference concentration layer 4 to the bottom surface of the base region 7). Accordingly, in the depletion-layer extension regions 6a, 6b, when a reverse bias is applied between the depletion-layer extension regions 6a, 6b and the opposing low concentration layer 3, a depletion layer having a sufficient thickness extends toward both the base regions 7a, 7b and the low concentration region 3 from a boundary with the low concentration layer 3 so that a breakdown voltage can be enhanced.

Further, a dVDS/dt-decreasing diffusion layer 30 which contains an n-type impurity (impurity of a first conductive type) at a concentration higher than a concentration of the impurity which the reference concentration layer 4 contains and can decrease dVDS/dt when the semiconductor device is turned off is formed on a surface of the reference concentration layer 4. The dVDS/dt-decreasing diffusion layer 30 is formed in a region shallower than the lower surfaces of the base regions 7a, 7b on the surface of the reference concentration layer 4. Further, the dVDS/dt-decreasing diffusion layer 30 contains an n-type impurity (impurity of a first conductive type) at a concentration lower than a concentration of a p-type impurity (impurity of a second conductive type) which the base regions 7a, 7b contain. To be more specific, the dVDS/dt-decreasing diffusion layer 30 contains phosphorous at a concentration of approximately 1.1×10¹⁶ to 3×10¹⁶ cm⁻³ and has a thickness of approximately 1.0 to 2.0 μm.

### 2. A Method for Manufacturing the Semiconductor Device

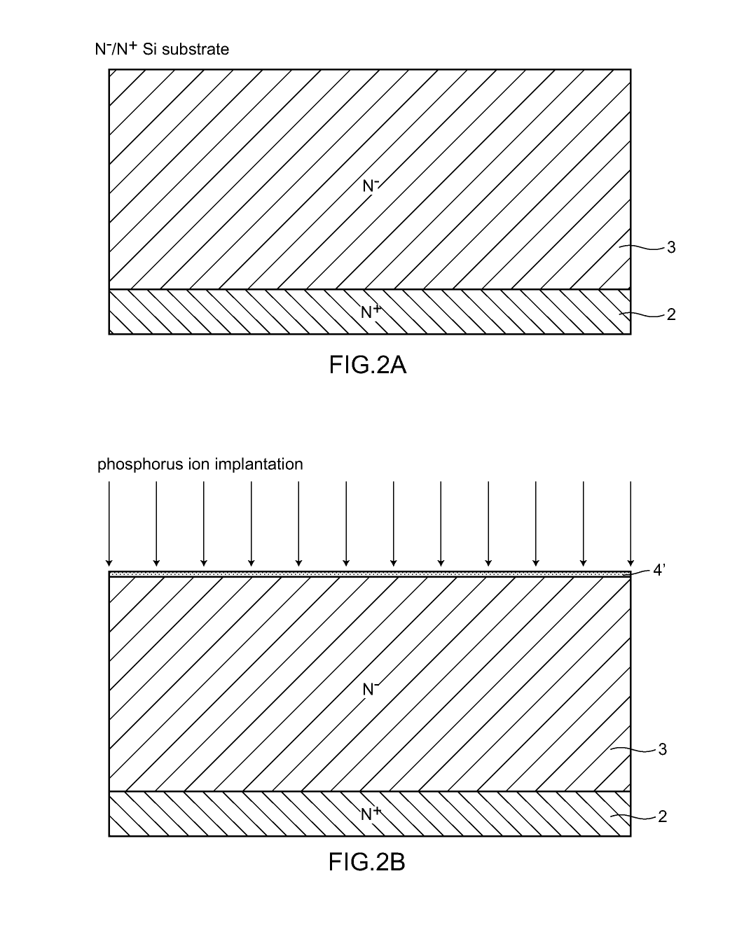

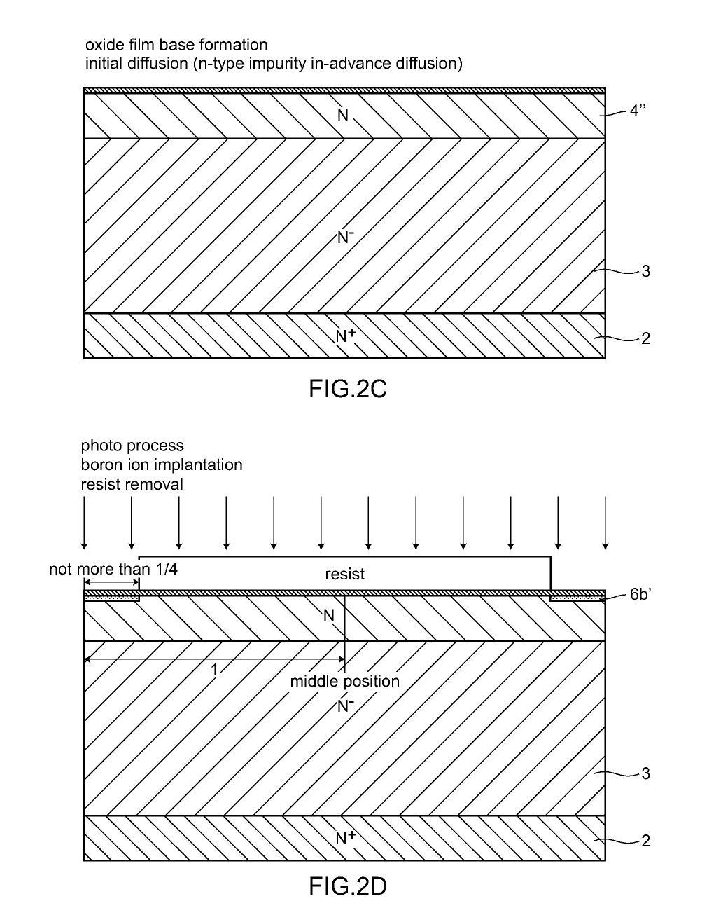

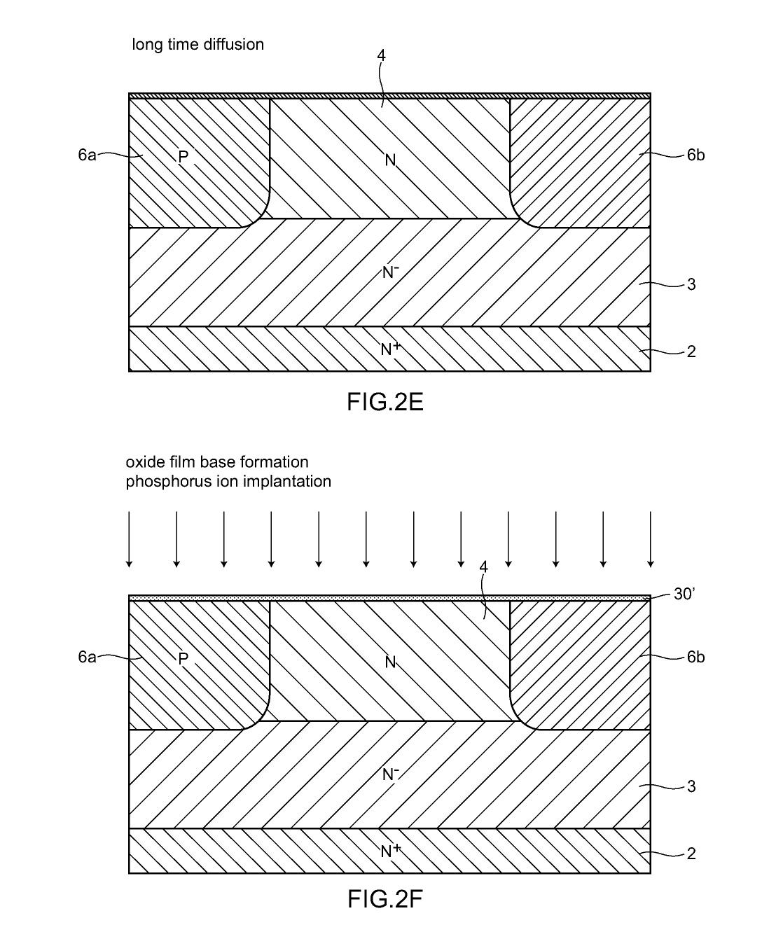

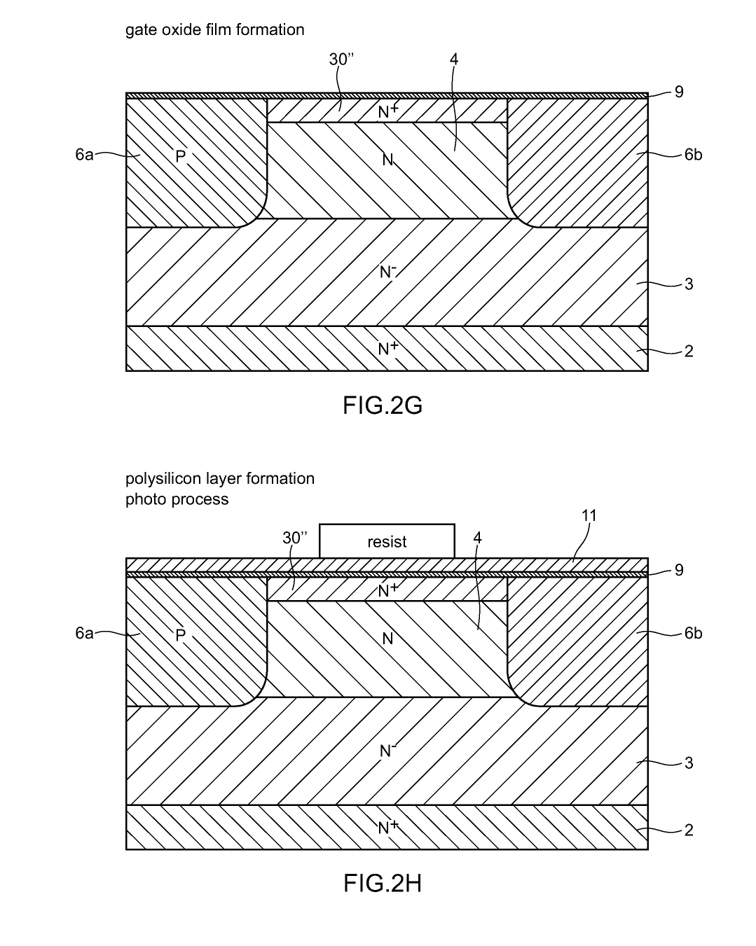

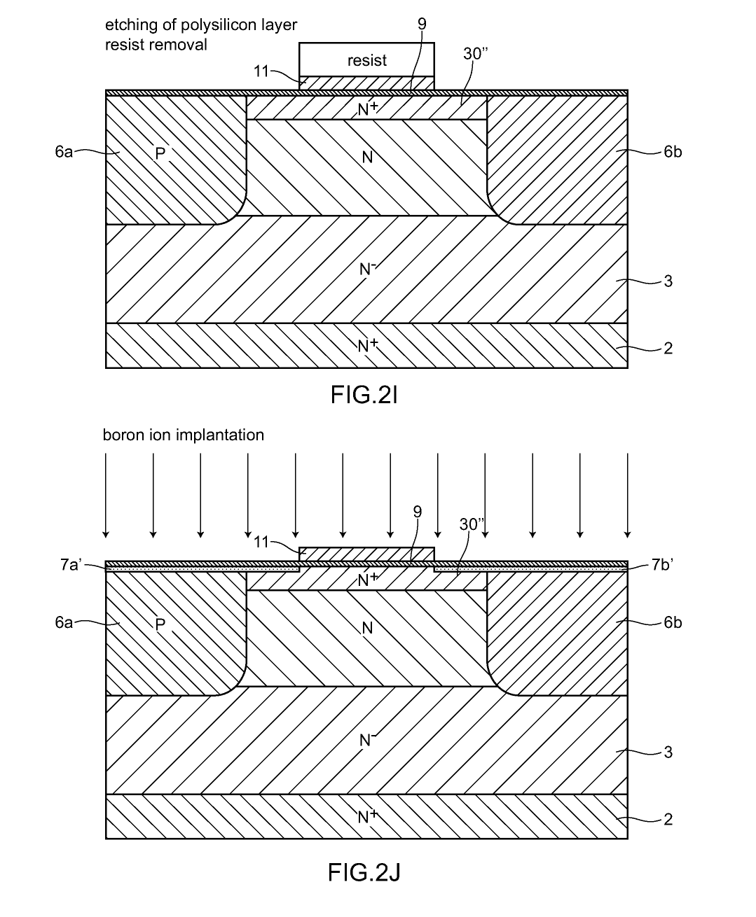

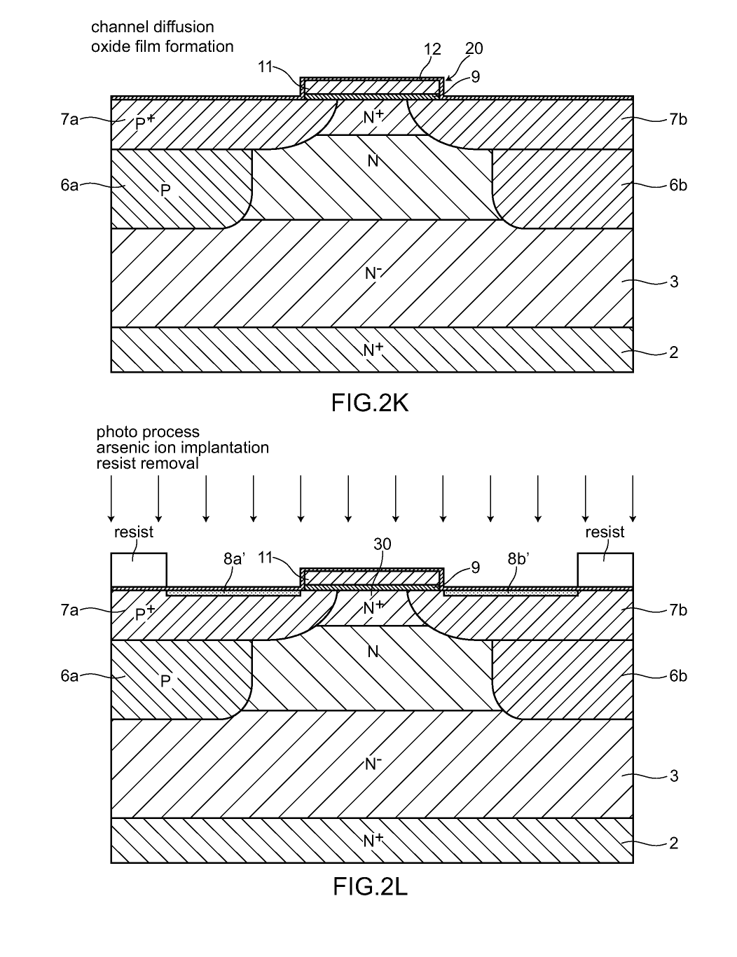

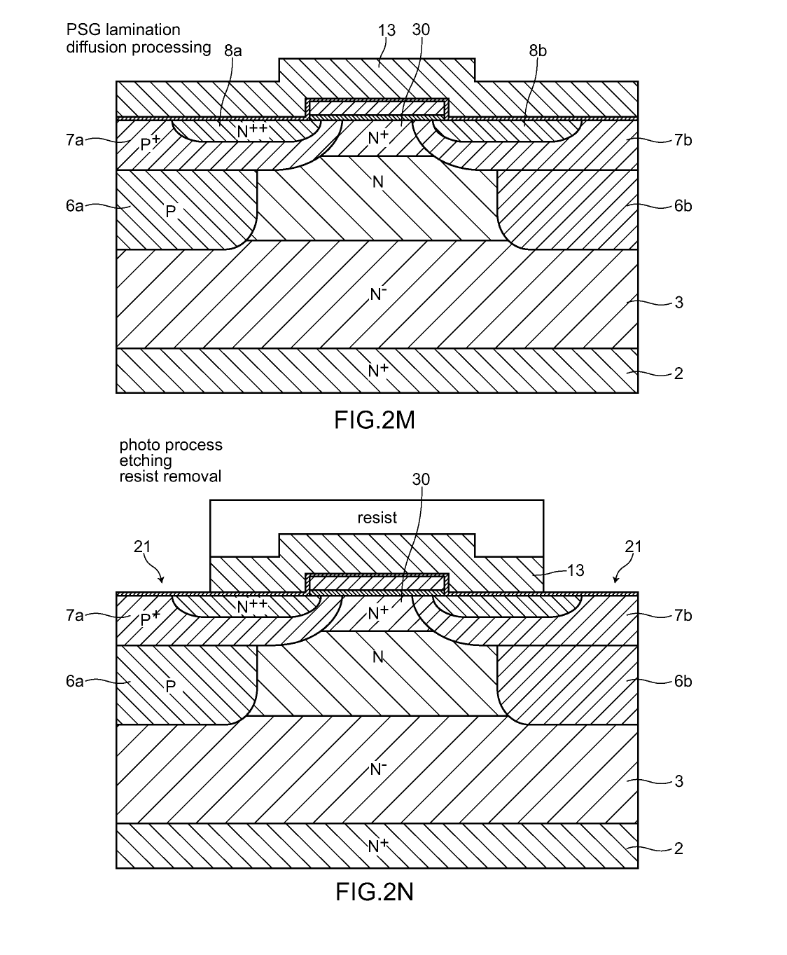

Next, the method for manufacturing the semiconductor device 10 of the present invention is explained in conjunction with FIG. 2A to FIG. 2O.

Firstly, a semiconductor substrate which is formed of a multilayered structure consisting of a layer containing antimony or phosphorus as an n-type impurity at a concentration of 1×10²⁰ cm⁻³ and a layer containing phosphorus as an n-type impurity at a concentration of 3×10¹⁴cm⁻³ is prepared. The lower layer of the prepared semiconductor substrate is provided for forming the drain layer 2 and the upper layer of the prepared semiconductor substrate is provided for forming the drift layer 5. At this stage, the reference concentration layer 4 of the drift layer 5 is not yet formed (FIG. 2A).

Phosphorus (P) which constitutes an n-type impurity for forming the reference concentration region 4 is ion-implanted to a surface of the prepared semiconductor substrate under conditions where energy is 100 keV and a dose of phosphorus is 4×10¹² to 8×10¹²cm⁻² (FIG. 2B). An oxide film base is formed and, thereafter, phosphorus which is ion-implanted is diffused in advance thus forming a phosphorus diffusion area having a predetermined depth in advance (FIG. 2C).

A resist is applied to the oxide film base by coating and then a mask pattern for ion implantation is formed by photolithography.

The mask pattern is provided for forming the depletion-layer extension regions 6a, 6b, and an impurity is ion-implanted through openings of the mask pattern (FIG. 2D). Here, an opening size of the openings of the mask pattern for the ion implantation is set to not more than a predetermined value. To be more specific, by reference to FIG. 1, assuming the distance from the position (middle position) B at ½ of a lateral width of the gate electrode structure 20 to the end portion E of the semiconductor device 10 as 1, the opening size is set to not more than ¼ of the distance. In this embodiment, the mask pattern is formed such that the opening size becomes 0.5 to 2 μm (since the semiconductor devices shown in FIG. 1 are arranged continuously in the actual manufacture as explained already, the corresponding opening size becomes 1 to 4 μm).

Here, the condition that the opening size of the mask pattern for the ion implantation is set to not more than ¼ is found by the inventors of the present invention through repeated experiments. That is, the opening of the mask pattern is formed at a position deviated from the position C by not less than ½ of the distance between the middle position B and the reference position C in the direction opposite to the polysilicon layer 11, and thereby a lateral end portion of an impurity diffusion surface formed by thermal diffusion or the like explained hereinafter can be formed at a position not reaching a curved portion of the diffusion layer of the base region 7a, 7b. Due to such a constitution, the distance between the opposing depletion-layer extension regions 6a, 6b to be formed later is prevented from being narrowed unnecessarily, and the ON-resistance can be maintained.

As explained above, boron (B) which constitutes the p-type impurity for forming the depletion-layer extension region 6 is ion-implanted to regions of the reference concentration region 4 spaced-apart from each other at a predetermined distance under conditions where a dose of boron is 1×10¹³ to 4×10¹³ cm⁻² using the above-mentioned mask pattern as a mask.

It is confirmed through repeated experiments that when patterning is carried out so that the opening size becomes less than ¼ and an ion implantation is carried out with the above-mentioned implantation condition, the depletion-layer extension region 6 which is formed by the thermal diffusion performed thereafter is formed into a desired shape so that preferable properties can be acquired.

In a thermal process of activating boron (B) as the impurity in the depletion-layer extension regions 6a, 6b which is a p-layer explained later, by forming a diffusion area of an n-type impurity having an in-advance predetermined degree of depth, the diffusion of the p-type impurity in the direction parallel to the surface of the semiconductor device (lateral direction) can be prevented. As a result, the distance between the depletion-layer extension region 6a and the opposing depletion-layer extension region 6b can be widened and formed with a width in accordance with a design value and hence, a width of the reference concentration region 4 can be widened compared to the corresponding distance in the related art so that the ON-resistance of the MOSFET is not increased. Further, to compare the ion implantation dose of phosphorous (P) and the ion implantation dose of boron (B) with each other, since the boron ion implantation dose is larger than the phosphorus ion implantation dose by a magnitude of one order, a diffusion speed of boron is faster than a diffusion speed of phosphorus and hence, the depletion-layer extension regions 6a, 6b can be diffused deeper than the n-type reference concentration layer 4.

Then, the diffusion is carried out for a long time for activating the implanted impurity. As a result, regions for forming the reference concentration layer 4 and the depletion-layer extension region 6a, 6b are formed on the semiconductor substrate (FIG. 2E). The impurity concentration of the reference concentration layer 4 (n layer) is set higher than the impurity concentration of the low concentration layer 3 (n⁻ layer). In addition, the low concentration layer 3 and the reference concentration layer 4 form the drift layer 5 where electrons move in an ON state due to an electric field.

Then, the oxide film base is removed by etching and, thereafter, the ion implantation of phosphorus (P) which constitutes an n-type impurity is carried out under conditions where energy is 100 keV and a dose of phosphorus is 5×10¹¹ to 5×10¹² cm⁻² (FIG. 2F). The implantation of phosphorous ions is carried out for forming a layer 30′ which will become the dVDS/dt-decreasing diffusion layer 30 later.

Thereafter, a new oxide film which constitutes the gate oxide film 9 is formed (FIG. 2G). Here, the ion-implanted phosphorus is diffused to some extent (see symbol 30″ in FIG. 2G).

Thereafter, a polysilicon layer for forming the gate electrode is formed on the oxide film. Then, a resist is applied to the polysilicon layer so as to form the gate electrode at a predetermined position, a photolithography (photo process) is carried out using a mask for forming a pattern for the gate electrode, and a resist pattern for etching the polysilicon layer is formed (FIG. 2H). The etching of the polysilicon layer is carried out by anisotropic etching, isotropic etching or the like using the resist pattern as a mask. As a result, the gate oxide film 9 having a predetermined shape and the polysilicon layer 11 which constitutes the gate electrode are formed at predetermined positions (FIG. 2I). Then, the resist used for such formation of the film and the layer is removed.

Then, boron (B) for forming a diffusion layer of the base regions 7a, 7b is ion-implanted using the above-mentioned polysilicon layer 11 as a mask under conditions where energy is 80 keV and a dose of boron is 4×10¹³ to 5×10¹³cm⁻² (FIG. 2J).

Then, diffusion processing (channel diffusion) is carried out for forming the diffusion layer for forming the base regions 7a, 7b and, thereafter, an oxide film 12 is formed on the periphery of the polysilicon layer (FIG. 2K). As a result, the gate electrode structure 20 which is constituted of the gate oxide film 9, the polysilicon layer 11 and the oxide film 12 is formed. Here, in carrying out the above-mentioned diffusion processing, due to the diffusion of phosphorous from a layer 30′ which becomes the dVDS/dt-decreasing diffusion layer 30, the dVDS/dt-decreasing diffusion layer 30 is also formed.

Then, to form the source regions 8a, 8b, a resist is applied to the base regions 7a, 7b and a photolithography is carried out using a mask for forming a source region thus forming a resist pattern. Thereafter, using the gate electrode structure 20 and the formed resist pattern as masks, arsenic (As) for forming a diffusion layer of the source regions 8a, 8b is ion-implanted under conditions where the energy is 100 keV and a dose of arsenic is 8×10¹⁵ to 10×10¹⁵cm⁻² (FIG. 2L) and, then, the resist pattern used as the mask is removed.

Next, PSG (Phosphorus Silicon Glass) 13 is laminated on the whole surface of the semiconductor substrate as an interlayer insulating film by CVD (Chemical Vapor Deposition). Thereafter, diffusion processing for forming diffusion layers of the source regions 8a, 8b and sintering (reflow processing for making a film surface planar) of the PSG 13 are carried out at the same time by heat treatment (FIG. 2M).

Thereafter, to form a contact for the base regions 7a, 7b and the source regions 8a, 8b, a resist is applied to the whole surface of the semiconductor substrate, and photolithography is carried out using a mask for forming the contact thus forming a resist pattern for forming the contact. Then, the PSG 13 and the oxide film 12 formed on the whole surface are etched using the resist pattern for forming the contact thus forming contact holes 21 in the PSG 13 and the oxide film 12 so as to expose parts of the base regions 7a, 7b and the source regions 8a, 8b, and then the resist is removed (FIG. 2N).

Next, using a sputtering method (or a vapor-deposition method), Al (aluminum) is deposited on the surface of the semiconductor substrate on which the PSG 13 is formed thus forming the source electrode 14 (surface electrode). The source electrode 14 is electrically connected to the source regions 8a, 8b and the base regions 7a, 7b via the aluminum deposited in the contact holes 21 and is insulated from the polysilicon layer 11 of the gate electrode structure 20 by the PSG 13 which constitutes the interlayer insulating layer. Here, the polysilicon layer 11 of the gate electrode structure 20 is electrically connected to the outside via a conductive material which are buried in the contact holes not shown in the drawing and are processed not to be short-circuited with the source electrode 14.

Further, a multi-layer metal film of Ti—Ni—Ag is deposited on the back surface of the semiconductor substrate, where the gate electrode structure 20 and the like are not formed, using a sputtering method (or a vapor-deposition method), and the drain electrode 1 (rear electrode) electrically connected to the drain layer 2 is formed (FIG. 2O).

Through the above processes, the semiconductor device 10 according to this embodiment can be formed (FIG. 1).

### 3. Advantageous Effects of the Semiconductor Device 10

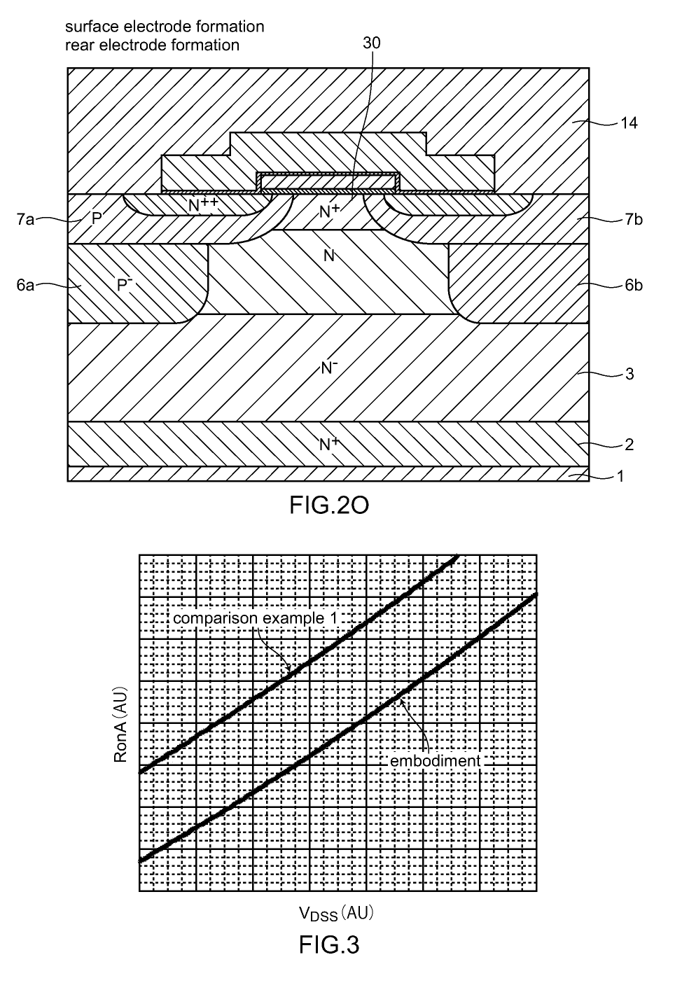

FIG. 3 is a graph showing a characteristic of the semiconductor device 10 according to this embodiment. In FIG. 3, symbol VDSS indicates a maximum voltage which can be applied between the drain and the source in a state where the gate and the source are short-circuited, and symbol RonA indicates the ON-resistance per unit active region. Here, data of a comparison example 1 is data of the semiconductor device described in patent document 2.

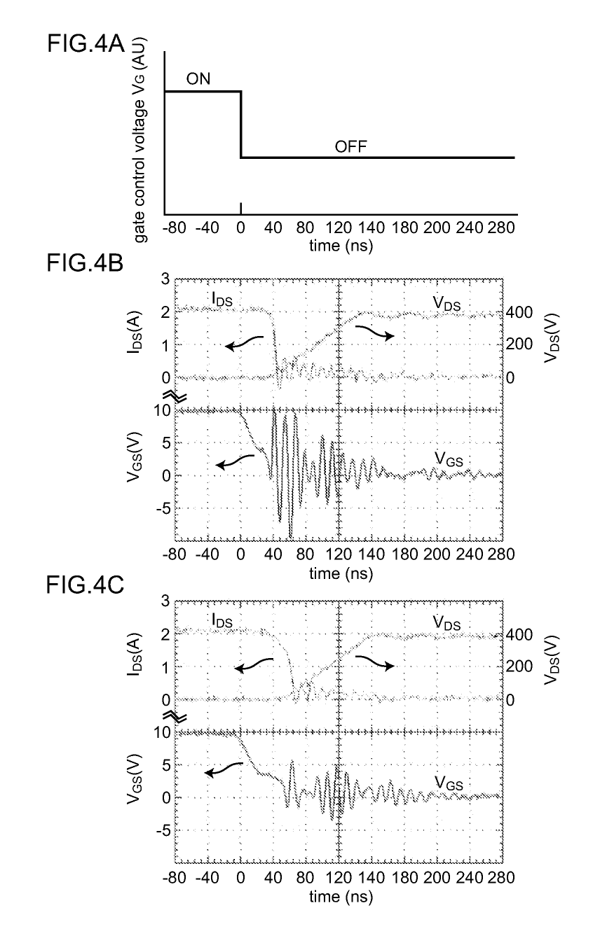

FIG. 4A to FIG. 4C are graphs for explaining an advantageous effect of the semiconductor device 10 according to this embodiment. In FIG. 4A to FIG. 4C, symbol t2 indicates a time at which a switch is turned off. FIG. 4A is the graph showing a gate control voltage. FIG. 4B is the graph showing a change of a voltage VDS between the drain and the source with time, a change of an electric current IDS between the drain and the source with time, and a change of a voltage VGS between the gate and the source with time in a semiconductor device according to a comparison example 2 (the semiconductor device 90 described in patent document 1). FIG. 4C is a graph showing a change of a voltage VDS between the drain and the source with time, a change of an electric current IDS between the drain and the source with time, and a voltage VGS between the gate and the source with time of the semiconductor device 10 according to this embodiment.

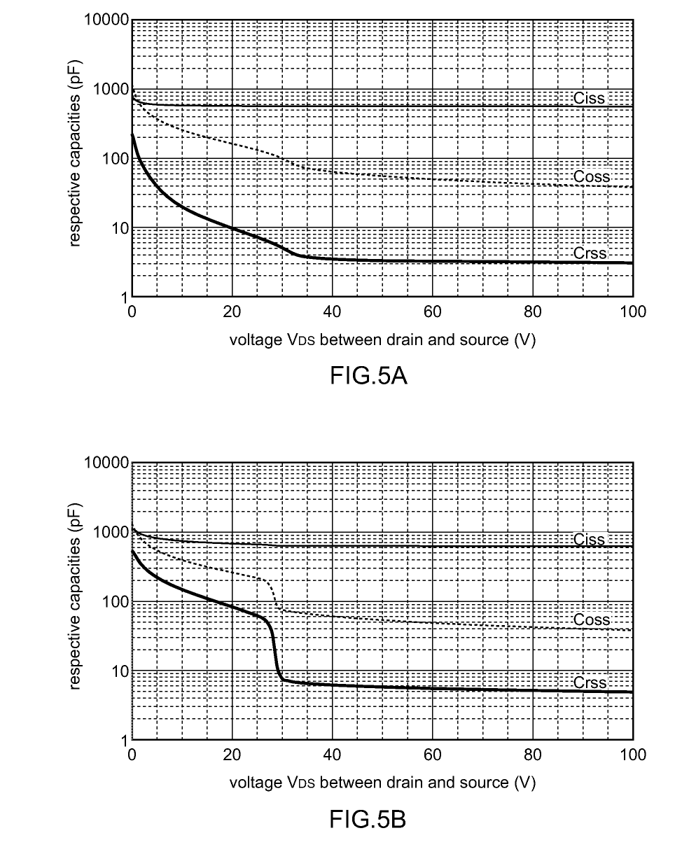

FIG. 5A and FIG. 5B are graphs for explaining the manner of operation of the semiconductor device 10 according to this embodiment. FIG. 5A is the graph showing a voltage VDS between the drain and the source and respective capacitances (input capacitance Ciss, output capacitance Coss, feedback capacitance Crss) between the gate and the drain of the semiconductor device according to the comparison example 2 (the semiconductor device 90 described in patent document 1). FIG. 5B is the graph showing a voltage VDS between the drain and the source, and respective capacitances (an input capacitance Ciss, an output capacitance Coss, a feedback capacitance Crss) between the gate and the drain of the semiconductor device 10 according to this embodiment.

In the semiconductor device 10 according to the embodiment having the constitution explained above, an inversion layer is formed in boundaries between the base regions 7a, 7b which constitute a back gate and the gate electrode when a voltage is applied between the source electrode 14 and the drain electrode 1 and an ON-control voltage is applied to the gate electrode (the polysilicon layer 11 of the gate electrode structure 20), that is, when a negative voltage (a negative potential) is applied to the source electrode 14, a positive voltage (a positive potential) is applied to the drain electrode, and a positive voltage is applied to the gate electrode and a negative voltage is applied to the source electrode 14 between the source electrode 14 and the gate electrode.

When the inversion layer is formed in a state where the voltage is applied between the source electrode 14 and the drain electrode 1, electrons supplied from the source electrode 14 sequentially move to the drain electrode 1 through the source regions 8a, 8b, the inversion layer of the base regions 7a, 7b, the reference concentration layer 4, the low concentration layer 3 and the drain layer 2. Due to such movement of the electrons, an electric current flows into the source electrode 14 from the drain electrode 1.

On the other hand, when a voltage is applied between the source electrode 14 and the drain electrode 1 and an OFF-control voltage is applied to the gate electrode (polysilicon layer 11), that is, when a negative voltage is applied to the source electrode 14 and a positive voltage is applied to the drain electrode, and a voltage between the source electrode 14 and the gate electrode is set to zero so that a voltage is not applied between the source electrode 14 and the gate electrode, an inversion layer is not formed in the boundary between the base region 7 and the gate electrode since the voltage is not applied to the gate electrode.

As a result, due to the voltage applied between the source electrode 14 and the drain electrode 1, as described previously, depletion layers are formed at the junctions between the p-type base region 7a, 7b and the n-type drift layer 5 and between the depletion-layer extension regions 6a, 6b and the n-type drift layer 5. The depletion layers gradually spread according to the voltage applied between the source electrode 14 and the drain electrode 1. When a voltage greater than a predetermined value is applied therebetween, the reference concentration layer 4 of the drift layer 5 formed between the opposing depletion-layer extension regions 6a, 6b and between the opposing base regions 7a, 7b is filled with the spreading depletion layers. Additionally, the depletion layers also spread in the low concentration layer 3 of the drift layer 5.

Here, the semiconductor device 10 according to this embodiment includes the depletion-layer extension regions 6a, 6b containing the p-type impurity at a low concentration and having a sufficient layer thickness. As a result, the semiconductor device 10 according to this embodiment enhances a breakdown voltage compared to the semiconductor device of the related art when a reverse bias is applied to the source electrode 14 and the drain electrode 1. Therefore, the semiconductor device 10 of this embodiment aims at the acceleration of the extension of the depletion layer into the depletion-layer extension regions 6a, 6b so that the increase in a field strength between the depletion-layer extension regions 6a, 6b and the low concentration layer 3 and the increase in a field strength between the depletion-layer extension regions 6a, 6b and the reference concentration layer 4 are prevented. As explained above, the semiconductor device 10 of this embodiment does not aim at the suppression of spreading of the depletion layer unlike the semiconductor device described in patent document 2. To the contrary, the semiconductor device of this embodiment adopts the structure which can alleviate a field strength in the depletion layer by extending the spreading distance of the depletion layer.

That is, to allow the depletion layer to extend sufficiently, the depletion-layer extension regions 6a, 6b of this embodiment contain the p-type impurity at a low concentration, and a thickness of the diffusion layer is set to a sufficient depth which is twice as large as the distance from the surface of the semiconductor device such as the depth of the base regions 7a, 7b compared to the conventional case. As a result, in this embodiment, the depletion layer spreading in the depletion-layer extension regions 6a, 6b can extend sufficiently to alleviate the field strength, and the extending depletion layer can alleviate the electric field. Accordingly, the semiconductor device 10 of this embodiment can reduce the lowering of a breakdown voltage caused by the field concentration whereby it is possible to acquire the favorable breakdown voltage characteristic.

Accordingly, when a reverse bias is applied between the source electrode 14 and the drain electrode 1, the depletion layer (depletion layer C) extends from the boundary between the depletion-layer extension regions 6a, 6b and the low concentration layer 3 toward both the depletion-layer extension regions 6a, 6b and the low concentration layer 3. The depletion layer extends further as the voltage of the reverse bias to be applied increases. At this time, in the same manner, the depletion layers (depletion layers A) extend to each other from the boundary between the base region 7a and the reference concentration layer 4 and from the boundary between the base region 7b and the reference concentration layer 4. Further, depletion layers (depletion layer B) extend to each other from the boundary between the depletion layer extension region 6a and the reference concentration layer 4 and the boundary between the depletion layer extension region 6b and the reference concentration layer 4, and these depletion layers are connected together at the middle position B. Accordingly, a portion where the electric field is significantly concentrated as in the related art is eliminated. That is, the field strength of each depletion layer A, B, and C is increased equally and hence, the breakdown voltage of the entire semiconductor device 10 can be increased. According to the semiconductor device 10 of this embodiment, the increase in the field strength of each PN-junction portion can be made substantially equal, and the breakdown voltage of the entire semiconductor device can be enhanced without causing the increase of the ON-resistance thereof.

The various setting conditions in the structure of the above-mentioned semiconductor device are found by the inventors of the present invention as a result of repeated experiments carried out using design rules and concentrations as parameters after actually preparing devices. In the semiconductor device manufactured based on the above-mentioned setting conditions, even when the side surface side of the base regions 7a, 7b are not covered with the depletion-layer extension regions 6a, 6b, the maximum voltage which can be applied between the drain and the source in a state where the gate and the source are short-circuited (hereinafter, referred to as VDSS) can be set higher, and the ON-resistance per unit active region (hereinafter, referred to as RonA) can be lowered whereby the favorable properties as shown in FIG. 3 can be acquired.

As has been explained heretofore, unlike the semiconductor device of the related art in which a depletion-layer extension region (the field alleviation layer of patent document 1) is formed on the side surface of the base region, in the semiconductor device 10 of this embodiment, the depletion-layer extension regions 6a, 6b are not formed on the opposing ends of the base regions 7a, 7b (including the curved region of the diffusion layer) so that the distance between the base regions 7a, 7b covering the source regions 8a, 8b can be narrowed whereby the miniaturization of the semiconductor device can be achieved while maintaining the ON-resistance without causing the increase of the ON-resistance. That is, according to the semiconductor device 10 of this embodiment, the diffusion regions of the base region, the depletion-layer extension region, the reference concentration layer, and the low concentration layer are formed with a thickness and an impurity concentration which allow the respective depletion layers to extend to make the respective field strength in the respective depletion layers substantially equal until the field strength of the PN junction corresponding to the respective depletion layers A, B, and C reach a value at which dielectric breakdown occurs, when the depletion layer A extends from the boundary between the base regions 7a, 7b and the reference concentration region 4, the depletion layer B extends from the boundary between the depletion-layer extension regions 6a, 6b and the reference concentration region 4 and the depletion layer C extends from the boundary between the depletion-layer extension regions 6a, 6b and the low concentration layer 3 in a process where the gate voltage is 0V and a voltage of a reverse bias applied between the source electrode 14 and the drain electrode 1 is increased.

Further, in the semiconductor device 10 according to this embodiment, since the dVDS/dt-decreasing diffusion layer 30 containing the n-type impurity at a concentration higher than a concentration of the n-type impurity which the reference concentration layer 4 contains is formed on the surface of the reference concentration layer 4. Accordingly, when the semiconductor device is turned off, the dVDS/dt-decreasing diffusion layer 30 can inhibit the spreading of the depletion layer from the gate oxide film 9 and the base regions 7a, 7b to the dVDS/dt-decreasing diffusion layer 30 difficult and hence, as shown in FIG. 5, the feedback capacitance Crss between the gate and the drain is not sharply lowered unlike the related art. As a result, unlike the related art, as shown in FIG. 4, the voltage VDS between the drain and the source is not sharply increased so that the gate parasitic oscillations are hardly generated when the switch is turned off. Accordingly, it is possible to effectively prevent a phenomenon that “Due to gate parasitic oscillations which are generated when the semiconductor device is turned off, a voltage VGS between a gate and a source may fall within an ON-voltage region again as in the case of the semiconductor device 90 of the related art”.

Further, the semiconductor device 10 according to this embodiment has the substantially same structure as the semiconductor device 90 of the related art (semiconductor device described in patent document 1) as the basic structure and hence, the semiconductor device can be miniaturized without causing the increase of the ON-resistance of the semiconductor device, and it is also possible to provide the semiconductor device having a preferable breakdown voltage characteristic.

Further, according to the semiconductor device 10 according to this embodiment, the resistance immediately below the gate electrode 20 can be lowered and hence, it is possible to reduce the ON-resistance of the semiconductor device compared to the semiconductor device 90 of the related art (semiconductor device described in patent document 1).

As a result, the semiconductor device 10 according to this embodiment becomes a semiconductor device which can be miniaturized without causing the increase of the ON-resistance of the semiconductor device, has a favorable breakdown voltage characteristic and can make the generation of gate parasitic oscillations more difficult compared to the semiconductor device of the related art.

In the semiconductor device 10 according to this embodiment, the dVDS/dt-decreasing diffusion layer 30 is formed in the region of the surface of the reference concentration layer 4 shallower than the lower surfaces of the base regions 7a, 7b. Due to such a constitution, there is no possibility that a thickness of the reference concentration layer 4 becomes noticeably thin due to the formation of the dVDS/dt-decreasing diffusion layer 30 and hence, the semiconductor device can maintain the preferable breakdown voltage characteristic as a whole.

In the semiconductor device 10 according to this embodiment, the dVDS/dt-decreasing diffusion layer 30 contains the n-type impurity (impurity of a first conductive type) at a concentration lower than the concentration of the impurity of the p-type impurity (the impurity of a second conductive type) which the base regions 7a, 7b contain. Due to such a constitution, in manufacturing the semiconductor device, it is unnecessary to take the interference between the dVDS/dt-decreasing diffusion layer 30 and the base regions 7a, 7b into consideration so that the manufacturing process can be simplified.

Although the present invention has been explained in conjunction with the embodiment heretofore, the present invention is not limited to the above-mentioned embodiment. The present invention can be carried out in various modifications without departing from the gist of the present invention. For example, the following modifications are conceivable.

(1) In the above-mentioned embodiment, the dVDS/dt-decreasing diffusion layer 30 is formed in the region of the surface of the reference concentration layer 4 shallower than the lower surfaces of the base regions 7a, 7b. However, the dVDS/dt-decreasing diffusion layer 30 may be formed in the region of the surface of the reference concentration layer 4 further shallower than ½ of a depth of the lower surfaces of the base regions 7a, 7b. Due to such a constitution, the reference concentration layer 4 (portion excluding the dVDS/dt-decreasing diffusion layer 30) can be made thicker compared to this embodiment and hence, the semiconductor device can maintain the favorable breakdown voltage characteristic as a whole. In this case, as the n-type impurity, it is preferable to use arsenic or antimony having a smaller diffusion coefficient than phosphorous in place of phosphorous.

(2) In the above-mentioned embodiment, the dVDS/dt-decreasing diffusion layer 30 contains the n-type impurity (the impurity of a first conductive type) at the concentration lower than the concentration of the p-type impurity (the impurity of a second conductive type) which the base regions 7a, 7b contain. However, the present invention is not limited to such a dVDS/dt-decreasing diffusion layer 30. The dVDS/dt-decreasing diffusion layer 30 may contain the n-type impurity (the impurity of a first conductive type) at the concentration equal to or higher than the concentration of the p-type impurity (the impurity of a second conductive type) which the base regions 7a, 7b contain.

(3) In the above-mentioned embodiment, the present invention is explained with respect to the case where the first conductive type is n-type and the second conductive type is p-type. However, the present invention is not limited to such a case. The first conductive type may be p-type and the second conductive type may be n-type.

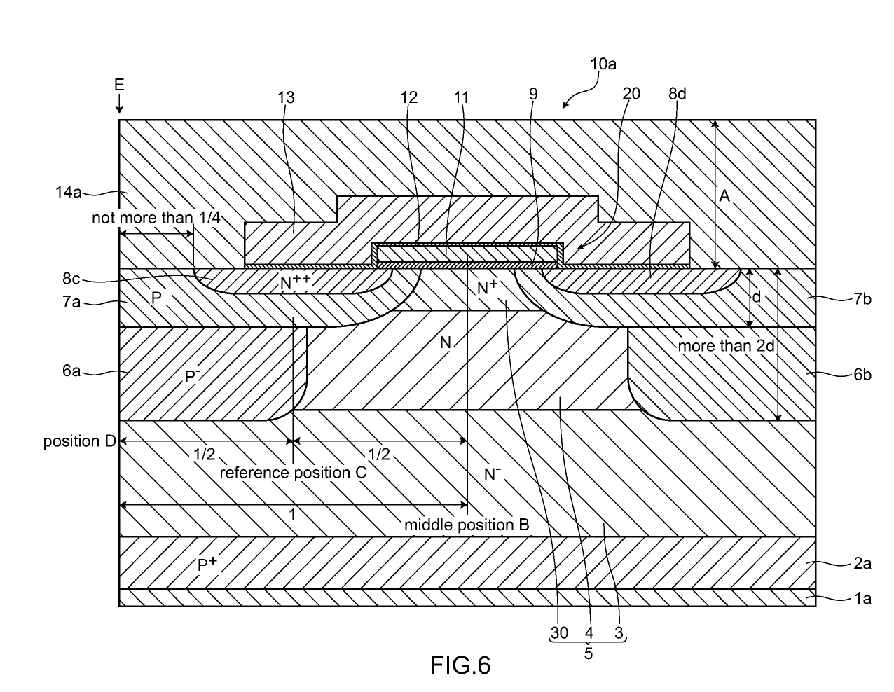

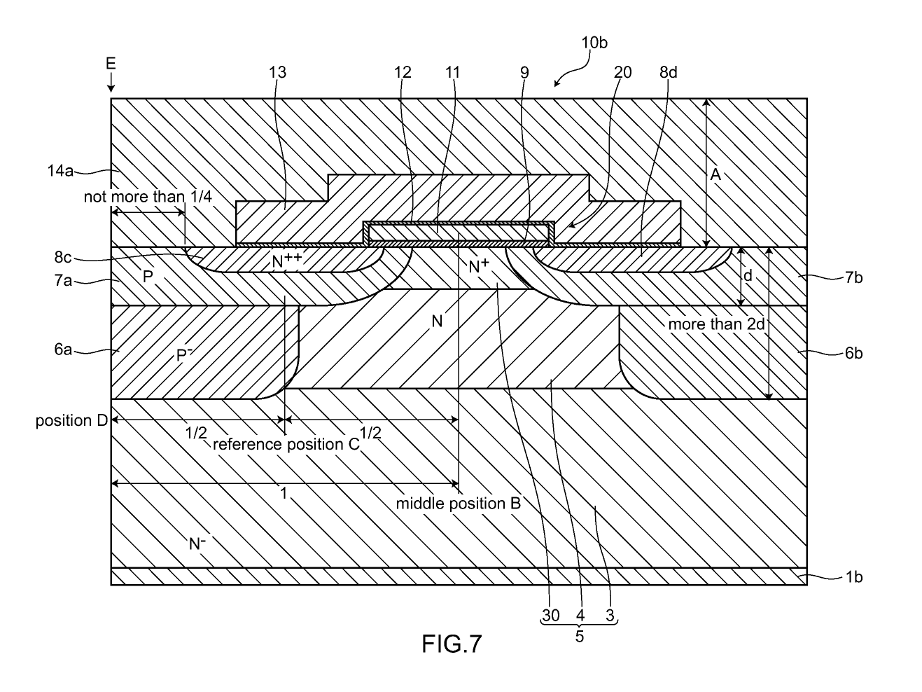

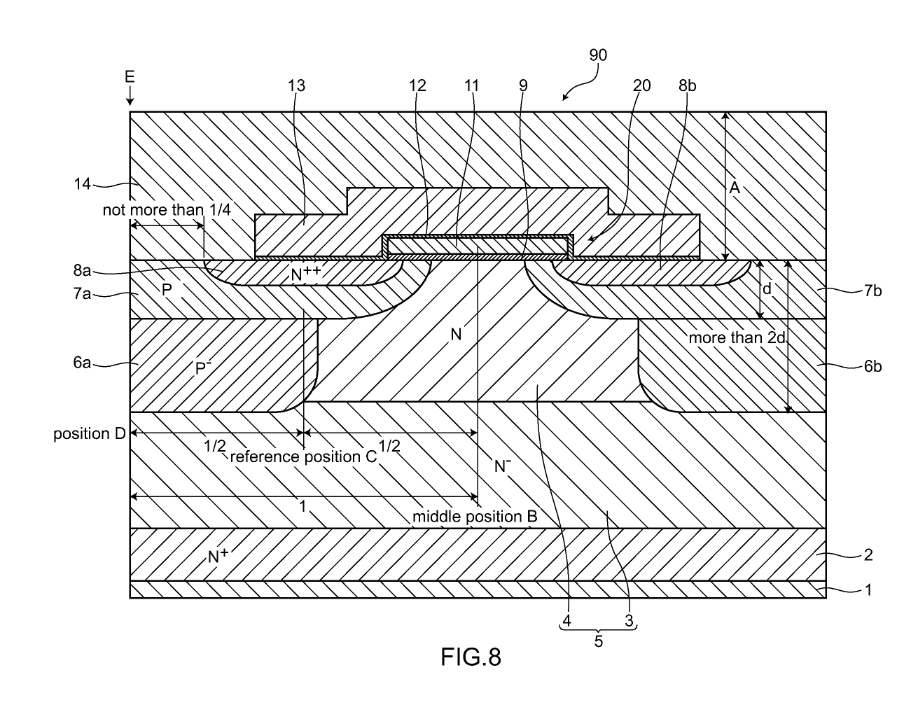

(4) In the above-mentioned embodiment, the present invention is explained using the semiconductor device 10 made of the MOSET. However, the present invention is not limited to such a case. FIG. 6 is a cross-sectional view of a semiconductor device 10a according to a modification 1 of this embodiment. FIG. 7 is a cross-sectional view of a semiconductor device 10b according to a modification 2 of this embodiment. In FIG. 6 and FIG. 7, symbols 8c, 8d indicate emitter regions, and symbol 14a indicates an emitter electrode. In FIG. 6, symbol 1a indicates a collector electrode and symbol 2a indicates a collector layer. Further, in FIG. 7, symbol 1b indicates a barrier metal layer. As shown in FIG. 6 and FIG. 7, the present invention is applicable to the semiconductor device 10a, 10b having a collector layer 2a and a barrier metal layer 1b below a low concentration layer 3 (IGBT or IGBT having a Schotky junction).

What is claimed is:

1. A semiconductor device comprising:
a drift layer which is constituted of a reference concentration layer containing an impurity of a first conductive type at a first reference concentration and a low concentration layer formed below the reference concentration layer and containing the impurity of a first conductive type at a concentration lower than the first reference concentration;
a gate electrode which is formed above the reference concentration layer interposing a gate insulation film;
a pair of semiconductor regions of a first conductive type which is formed on a surface of the reference concentration layer in the vicinity of respective end portions of the gate electrode and contains the impurity of a first conductive type at a concentration higher than the first reference concentration;
a pair of base regions which surrounds the respective semiconductor regions of a first conductive type and contain an impurity of a second conductive type at a second reference concentration;
a first electrode which is electrically connected to the semiconductor regions of a first conductive type and the base regions; and
depletion-layer extension regions which are formed in the reference concentration layer below the base regions and contain an impurity of a second conductive type at a concentration lower than the second reference concentration, wherein
the depletion-layer extension regions are formed such that a lower surface of the depletion-layer extension region is deeper than a boundary between the low concentration layer and the reference concentration layer and projects into the low concentration layers, and
a dVDS/dt-decreasing diffusion layer which contains the impurity of a first conductive type at a concentration higher than the concentration of the impurity which the reference concentration layer contains and decreases dVDS/dt when the semiconductor device is turned off is formed on a surface of the reference concentration layer.

2. The semiconductor device according to claim 1, wherein the dVDS/dt-decreasing diffusion layer is formed in a region of a surface of the reference concentration layer shallower than the lower surfaces of the base regions.

3. The semiconductor device according to claim 2, wherein the dVDS/dt-decreasing diffusion layer is formed in a region of the surface of the reference concentration layer shallower than a depth which is ½ of a depth of the lower surfaces of the base regions.

4. The semiconductor device according to claim 1, wherein the dVDS/dt-decreasing diffusion layer contains the impurity of a first conductive type at a concentration lower than a concentration of the impurity of a second conductive type which the base region contains.

5. The semiconductor device according to claim 1, wherein the semiconductor region of a first conductive type is a source region, the first electrode is a source electrode, and the semiconductor device further includes a drain layer which is formed below the low concentration layer and contains the impurity of a first conductive type at a concentration higher than the first reference concentration and a drain electrode which is formed below the drain layer, a voltage being applied between the first electrode and the drain electrode, and the semiconductor device is a MOSFET.

6. The semiconductor device according to claim 1, wherein the semiconductor region of a first conductive type is an emitter region, the first electrode is an emitter electrode, and the semiconductor device further includes a collector layer which is formed below the low concentration layer and contains an impurity of a second conductive type, and a collector electrode which is formed below the collector layer, a voltage being applied between the first electrode and the collector electrode, and the semiconductor device is an IGBT.

7. The semiconductor device according to claim 1, wherein the semiconductor region of a first conductive type is an emitter region, the first electrode is an emitter electrode, and the semiconductor device further includes a barrier metal layer which is formed below the low concentration layer, a voltage being applied between the first electrode and the barrier metal layer, and the semiconductor device is an IGBT which includes a Schottky junction.

8. A method for manufacturing a semiconductor device using a semiconductor substrate which includes a low concentration layer containing an impurity of a first conductive type, the method comprising the steps of:
forming a drift layer which is constituted of a reference concentration layer and a low concentration layer, the reference concentration layer being formed by implanting an impurity of a first conductive type at a first reference concentration higher than the impurity concentration of the low concentration layer into the low concentration layer and by thermal diffusion;
forming depletion-layer extension regions by implanting an impurity of a second conductive type into regions of the reference concentration layer which are spaced-apart from each other by a predetermined distance;
performing thermal diffusion for activating the impurity of a second conductive type implanted into the depletion-layer extension regions;
forming a dVDS/dt-decreasing diffusion layer by implanting the impurity of a first conductive type into the reference concentration layer and by performing thermal diffusion;
forming a gate pattern between the depletion-layer extension regions by forming an oxide film on the semiconductor substrate and, thereafter, depositing a polysilicon layer on the oxide film;
forming base regions by implanting an impurity of a second conductive type at a second reference concentration higher than the impurity concentration of the depletion-layer extension regions using the gate pattern as a mask for forming the base regions and by performing thermal diffusion; and
forming semiconductor regions of a first conductive type by implanting an impurity of a first conductive type into the base regions at a concentration higher than the first reference concentration using the gate pattern as a mask for forming the semiconductor regions of a first conductive type and by performing thermal diffusion, wherein
lower surfaces of the depletion-layer extension regions are positioned deeper than a boundary between the low concentration layer and the reference concentration layer and are formed with a depth where the lower surfaces projects into the low concentration layer.

9. A method for manufacturing a semiconductor device according to claim 8, wherein the semiconductor device is a MOSFET, and the semiconductor substrate which includes the low concentration layer containing the impurity of a first conductive type is a semiconductor substrate which is constituted of a drain layer containing an impurity of a first conductive type at a predetermined concentration, and a low concentration layer which is formed above the drain layer and contains an impurity of a first conductive type at a concentration lower than the predetermined concentration.

10. A method for manufacturing a semiconductor device according to claim 8, wherein the semiconductor device is an IGBT, and the semiconductor substrate which includes the low concentration layer containing the impurity of a first conductive type is a semiconductor substrate which is constituted of a collector layer containing an impurity of a second conductive type and a low concentration layer which is formed above the collector layer and contains an impurity of a first conductive type.

11. A method for manufacturing a semiconductor device according to claim 8, wherein the semiconductor device is an IGBT, the semiconductor substrate which includes the low concentration layer containing the impurity of a first conductive type is a semiconductor substrate which is constituted of the low concentration layer, and the method further includes a step of forming a barrier metal layer below the low concentration layer.
